(19) United States
(12) Patent Application Publication
(10) Pub. No.: US 2025/0297048 A1
(43) Pub. Date: Sep. 25, 2025

(54) (METH)ACRYLATE-BASED RESIN, AND DRY FILM SOLDER RESIST COMPRISING SAME

(71) Applicant: LG CHEM, LTD., Seoul (KR)

(72) Inventors: Jeong Wook MUN, Daejeon (KR); Woo Jae JEONG, Daejeon (KR); Seung Hwan KIM, Daejeon (KR); Yu Ra KIM, Daejeon (KR)

(21) Appl. No.: 18/730,201

(22) PCT Filed: Apr. 19, 2023
(86) PCT No.: PCT/KR2023/005278

§ 371 Date: Feb. 12, 2025

(30) Foreign Application Priority Data
Jul. 7, 2022 (KR) 10-2022-0083755

(51) Int. Cl. C08F 283/10; B23K 1/20; B23K 35/36; B23K 35/365

(52) U.S. Cl. CPC C08F 283/10; B23K 1/20; B23K 35/3613; B23K 35/365

(57) ABSTRACT

A (meth)acrylate-based resin, and a dry film solder resist including the same. The (meth)acrylate-based resin reduces generation of chlorine ions is reduced by controlling the types of base resin and reactants used during the preparation process.

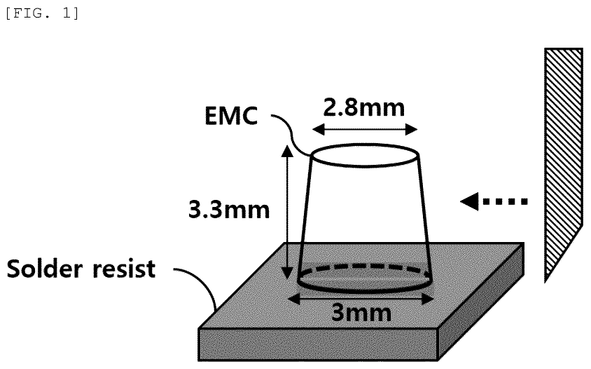

### CROSS-REFERENCE TO RELATED APPLICATIONS

This specification is a National Stage Application of International Application No. PCT/KR2023/005278 filed on Apr. 19, 2023, which claims priority to and the benefit of Korean Patent Application No. 10-2022-0083755, filed with the Korean Intellectual Property Office on Jul. 7, 2022, the contents of which are incorporated herein by reference in their entirety.

### TECHNICAL FIELD

The present disclosure relates to a (meth)acrylate-based resin and a dry film solder resist including the same, and in particular, to a (meth)acrylate-based resin reducing generation of chlorine ions by controlling the types of base resin and reactants used during the preparation process, and a dry film solder resist including the same.

### BACKGROUND ART

As various electronic devices become smaller and lighter in weight, solder resists capable of forming a fine opening pattern are used in printed circuit boards, semiconductor package boards, flexible circuit boards and the like.

As for the solder resist, properties such as developability, high resolution, insulation, adhesiveness, soldering heat resistance, and gold plating resistance are generally required.

An acid group-containing acrylate resin used in an existing solder resist has been used by acrylating an epoxy resin with acrylic acid, and then reacting an acid anhydride therewith to prepare an acrylate containing an acid group. When prepared using such a preparation method, a large amount of chlorine ions is included during the epoxy resin preparation process, resulting in migration of copper included in a circuit, and as a result, insulation is reduced, causing a problem of poor reliability. In addition, when a large amount of acid groups is included in the acid group-containing acrylate, a problem of filler residue occurs, and including a small amount of acid groups causes a problem of reducing developability.

Accordingly, in order to manufacture a solder resist with enhanced developability, residue and insulation, there have been demands for improving a method for preparing an acrylate resin.

### BRIEF DESCRIPTION

### Technical Problem

The present disclosure is directed to providing a (meth)acrylate-based resin capable of enhancing insulation reliability by controlling types and contents of base resin and reactants included in the resin composition for preparing a dry film solder resist, thereby reducing chlorine ions generated during the process for preparing the (meth)acrylate-based resin, and a dry film solder resist including the same.

However, objects to be addressed by the present disclosure are not limited to the object mentioned above, and other objects not mentioned will be clearly appreciated by those skilled in the art from the following description.

### Technical Solution

One embodiment of the present disclosure provides a (meth)acrylate-based resin including: a first resin including repeat units of the following Chemical Formula 1 and the following Chemical Formula 2; and a second resin including repeat units of the following Chemical Formula 3 and the following Chemical Formula 4.

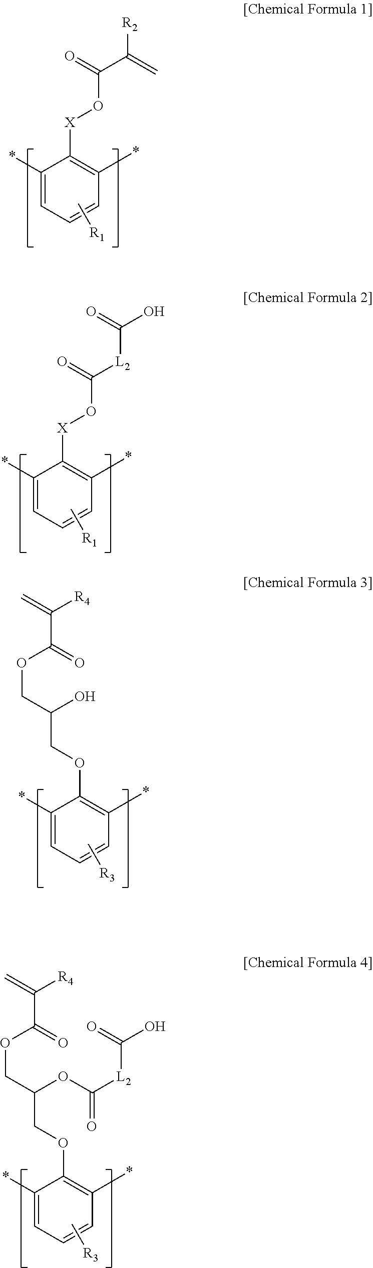

In Chemical Formula 1 to Chemical Formula 4,
R1, R2, R3 and R4 are each independently a substituted or unsubstituted alkyl group having 1 to 20 carbon atoms, a substituted or unsubstituted alkenyl group having 2 to 20 carbon atoms, or a substituted or unsubstituted aryl group having 6 to 15 carbon atoms,
X is a single bond or 0-L1,
L1 and L2 are each independently a substituted or unsubstituted alkylene group having 1 to 10 carbon atoms, a substituted or unsubstituted alkenylene group having 2 to 10 carbon atoms, a substituted or unsubstituted cycloalkylene group having 3 to 10 carbon atoms, a substituted or unsubstituted cycloalkenylene group having 3 to 10 carbon atoms, or a substituted or unsubstituted arylene group having 6 to 15 carbon atoms, and
* represents a connection point.

One embodiment of the present disclosure provides a resin composition including the (meth)acrylate-based resin and an additive.

One embodiment of the present disclosure provides a dry film solder resist including the resin composition or a cured product of the resin composition.

### Advantageous Effects

A (meth)acrylate-based resin according to one embodiment of the present disclosure is capable of reducing chlorine ions generated during the preparation process.

The (meth)acrylate-based resin according to one embodiment of the present disclosure is capable of enhancing low dielectric constant properties.

A resin composition according to one embodiment of the present disclosure contains only a small amount of chlorine ions, and therefore, is capable of enhancing insulation reliability and lifetime, suppressing an occurrence of migration, and delaying the time of occurrence.

A dry film solder resist according to one embodiment of the present disclosure is capable of strengthening developability, and enhancing soldering adhesiveness by reducing residue.

The dry film solder resist according to one embodiment of the present disclosure includes an active ester structure, and therefore, is capable of enhancing adhesive strength with an epoxy molding compound (EMC). In addition, due to the enhanced adhesive strength, a process of plasma treating the solder resist may be skipped before the epoxy molding compound process.

Effects of the present disclosure are not limited to the above-described effects, and effects not mentioned will be clearly appreciated by those skilled in the art from the present specification and accompanying drawing.

### BRIEF DESCRIPTION OF THE DRAWINGS

The FIGURE is a diagram illustrating a method for evaluating adhesive strength between a solder resist surface and an epoxy molding compound in Experimental Example 6.

### DETAILED DESCRIPTION

Throughout the present specification, a description of a certain part “including” certain constituents means capable of further including other constituents, and does not exclude other constituents unless particularly stated on the contrary.

Throughout the present specification, a description of a certain member being placed “on” another member includes not only a case of the certain member being in contact with the another member but a case of still another member being present between the two members.

Throughout the present specification, a unit “parts by weight” may mean a ratio of weights between each component.

Throughout the present specification, a unit “parts by mole” may mean a ratio of moles between each component.

Throughout the present specification, “(meth)acrylate” is used as a generic term for acrylate and methacrylate.

Throughout the present specification, “A and/or B” means “A and B, or A or B”.

Throughout the present specification, a term “repeat unit” may mean a form in which a monomer is reacted in a polymer, and specifically, may mean a form in which a monomer undergoes a polymerization reaction to form a skeleton, for example, a main chain or a side chain, of the polymer.

Throughout the present specification, “weight average molecular weight” and “number average molecular weight” of a certain compound may be calculated using a molecular weight and molecular weight distribution of the compound. Specifically, tetrahydrofuran (THF) and a compound are introduced to a 1 ml glass bottle to prepare a sample having a compound concentration of 1 wt %, and after filtering a standard sample (polystyrene) and the sample through a filter (pore size of 0.45 μm), the result is injected to a GPC injector, and an elution time of the sample is compared with a calibration curve of the standard sample to obtain a molecular weight and molecular weight distribution of the compound. Herein, Infinity II 1260 (Agilent Technologies) may be used as a measuring device, and the flow rate may be set at 1.00 mL/min and the column temperature at 40.0° C.

Throughout the present specification, a “glass transition temperature (Tg)” may be measured using a differential scanning analysis (DSC). Specifically, a sample is heated at a heating rate of 5° C./min in a temperature range of −60° C. to 150° C. using a DSC (differential scanning calorimeter, DSC-STAR3, METTLER TOLEDO), and by conducting two cycles of experiments in the above-mentioned section, a midpoint of the DSC curve prepared as a point having a quantity of thermal change is measured to determine the glass transition temperature.

Throughout the present specification, “substitution” may mean that a hydrogen atom bonding to a carbon atom of a compound is changed to another substituent, and the position of substitution is not limited as long as it is a position at which the hydrogen atom is substituted, that is, a position at which a substituent is capable of substituting, and when two or more substituents substitute, the two or more substituents may be the same as or different from each other.

Throughout the present specification, “substituted or unsubstituted” means being substituted with one, two or more substituents selected from the group consisting of a hydroxyl group, an alkyl group, a cycloalkyl group, and an aryl group, or being substituted with a substituent in which two or more substituents of the substituents exemplified above are linked together, or having no substituents. For example, the “substituent in which two or more substituents are linked” may be a biphenyl group. In other words, a biphenyl group may be an aryl group, or may be interpreted as a substituent in which two phenyl groups are linked together.

Throughout the present specification, an “alkyl group” may mean a linear or branched form.

Throughout the present specification, an “alkylene group” may mean having two bonding sites in an alkyl group, that is, a divalent group.

Throughout the present specification, an “alkenylene group” may mean having two bonding sites in an alkene group, that is, a divalent group.

Throughout the present specification, an “aryl group” may be a monocyclic or polycyclic group.

Throughout the present specification, an “arylene group” may be a monocyclic or polycyclic group, and may mean having two bonding sites in an aryl group, that is, a divalent group.

Hereinafter, the present disclosure will be described in more detail.

An acid group-containing (meth)acrylate-based resin used in an existing dry film solder resist (DFSR) has been prepared by acrylating an epoxy resin with acrylic acid, and then reacting an acid anhydride therewith. When prepared using such a preparation method, a large amount of chlorine ions is included in the prepared (meth)acrylate resin (about 800 mg/kg or greater). Accordingly, when the (meth)acrylate resin prepared using the existing preparation method is used in a circuit, migration of copper included in the circuit occurs, and as a result, insulation is reduced, causing a problem of poor reliability.

One embodiment of the present disclosure provides a (meth)acrylate-based resin including: a first resin including repeat units of the following Chemical Formula 1 and the following Chemical Formula 2; and a second resin including repeat units of the following Chemical Formula 3 and the following Chemical Formula 4.

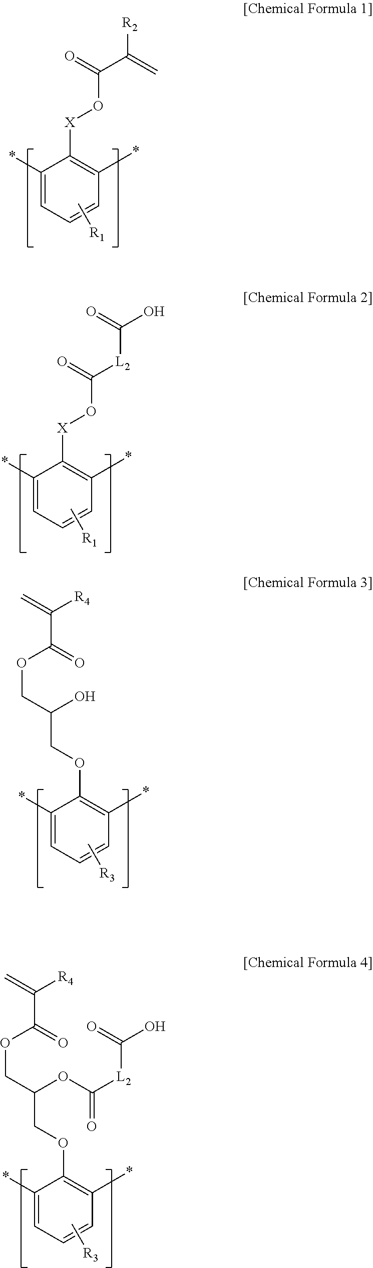

In Chemical Formula 1 to Chemical Formula 4,
R1, R2, R3 and R4 are each independently a substituted or unsubstituted alkyl group having 1 to 20 carbon atoms, a substituted or unsubstituted alkenyl group having 2 to 20 carbon atoms, or a substituted or unsubstituted aryl group having 6 to 15 carbon atoms,
X is a single bond or 0-L1,
L1 and L2 are each independently a substituted or unsubstituted alkylene group having 1 to 10 carbon atoms, a substituted or unsubstituted alkenylene group having 2 to 10 carbon atoms, a substituted or unsubstituted cycloalkylene group having 3 to 10 carbon atoms, a substituted or unsubstituted cycloalkenylene group having 3 to 10 carbon atoms, or a substituted or unsubstituted arylene group having 6 to 15 carbon atoms, and
* represents a connection point.

The “alkylene group” may mean a group including a saturated hydrocarbon group bonding to the rest of the molecule by two different bonds, the “alkenylene group” may mean a group including a carbon-carbon double bond as an unsaturated hydrocarbon group bonding to the rest of the molecule by two different bonds, and the “arylene group” may mean a group including an aromatic ring bonding to the rest of the molecule by two different bonds.

The “alkyl group” may mean a group including a saturated hydrocarbon group bonding to the rest of the molecule by one bond, and the “alkenyl group” may mean a group including a carbon-carbon double bond as an unsaturated hydrocarbon group bonding to the rest of the molecule by one bond.

The “single bond” means a direct bond, and specifically, when X is a single bond in Chemical Formula 1 and Chemical Formula 2, benzene and oxygen may directly bond.

The (meth)acrylate-based resin according to one embodiment of the present disclosure may reduce chlorine ions generated during the preparation process, and may enhance low dielectric constant properties. In addition, in the acid group-containing (meth)acrylate-based resin, the acid group performs a role of a developing group, and since the acid group is away from the main chain in the (meth)acrylate-based resin according to one embodiment of the present specification compared to in existing materials, developability is excellent and an effect of reducing residue is obtained.

According to one embodiment of the present disclosure, the first resin including the repeat units of Chemical Formula 1 and Chemical Formula 2; and the second resin including the repeat units of Chemical Formula 3 and Chemical Formula 4 are included. As described above, by including the first resin including the repeat units of Chemical Formula 1 and Chemical Formula 2; and the second resin including the repeat units of Chemical Formula 3 and Chemical Formula 4, generation of chlorine ions may be minimized during the (meth)acrylate-based resin preparation process.

According to one embodiment of the present disclosure, the (meth)acrylate-based resin includes the first resin including the repeat units of Chemical Formula 1 and Chemical Formula 2. The (meth)acrylate-based resin includes the repeat units of Chemical Formula 1 including a (meth)acrylate group at the end and Chemical Formula 2 including a carboxyl group at the end. By the (meth)acrylate-based resin including the first resin including the repeat units 41 Formula 1 and Chemical Formula 2, insulation reliability of a dry film solder resist including the (meth)acrylate-based resin may be enhanced.

According to one embodiment of the present disclosure, the repeat unit of Chemical Formula 1 and the repeat unit of Chemical Formula 2 may have a molar ratio of 9:1 to 1:9 in the (meth)acrylate-based resin. Specifically, the repeat unit of Chemical Formula 1 and the repeat unit of Chemical Formula 2 may have a molar ratio of 8:2 to 2:8, 7:3 to 3:7 or 6:4 to 4:6. By controlling the molar ratio of the repeat unit of Chemical Formula 1 and the repeat unit of Chemical Formula 2 included in the (meth)acrylate-based resin within the above-described range, chlorine ions generated during the (meth)acrylate-based resin preparation process may be minimized.

According to one embodiment of the present disclosure, the (meth)acrylate-based resin may include the repeat unit of Chemical Formula 1 in an amount of greater than or equal to 10 parts by mole and less than or equal to 90 parts by mole with respect to 100 parts by mole of the repeat units of the first resin. By controlling the molar ratio of the repeat unit of Chemical Formula 1 within the above-described range, an occurrence of migration may be suppressed and the time of occurrence may be delayed.

According to one embodiment of the present disclosure, the (meth)acrylate-based resin may include the repeat unit of Chemical Formula 2 in an amount of greater than or equal to 10 parts by mole and less than or equal to 90 parts by mole with respect to 100 parts by mole of the repeat units of the first resin. By controlling the molar ratio of the repeat unit of Chemical Formula 2 within the above-described range, an occurrence of migration may be suppressed and the time of occurrence may be delayed.

According to one embodiment of the present disclosure, the first resin may be prepared by reacting:
ia) a first base resin including a repeat unit of the following Chemical Formula 5 or ib) a reaction product of the first base resin and a compound of the following Chemical Formula 6; and
iia) a compound pf the following Chemical Formula 7, or iib) a compound of the following Chemical Formula 8.

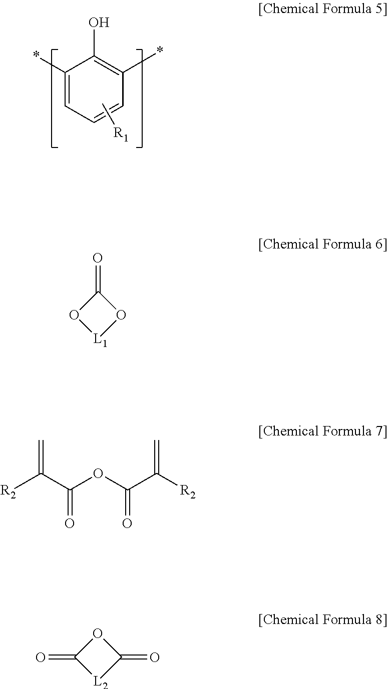

In Chemical Formula 5 to Chemical Formula 8,
R1 and R2 are each independently a substituted or unsubstituted alkyl group having 1 to 20 carbon atoms, a substituted or unsubstituted alkenyl group having 2 to 20 carbon atoms, or a substituted or unsubstituted aryl group having 6 to 15 carbon atoms,
L1 and L2 are each independently a substituted or unsubstituted alkylene group having 1 to 10 carbon atoms, a substituted or unsubstituted alkenylene group having 2 to 10 carbon atoms, a substituted or unsubstituted cycloalkylene group having 3 to 10 carbon atoms, a substituted or unsubstituted cycloalkenylene group having 3 to 10 carbon atoms, or a substituted or unsubstituted arylene group having 6 to 15 carbon atoms, and
* represents a connection point.

According to one embodiment of the present disclosure, the first base resin may be a novolac resin. Specifically, the first base resin may be a cresol novolac resin. When the first base resin is a novolac resin, chlorine ions generated during the (meth)acrylate-based resin preparation process may be minimized.

According to one embodiment of the present disclosure, the first base resin may have a hydroxyl group equivalent of greater than or equal to 100 g/eq and less than or equal to 150 g/eq. According to one embodiment of the present disclosure, the reaction product of the first base resin and the compound represented by Chemical Formula 6 has a hydroxyl group equivalent of greater than or equal to 150 g/eq and less than or equal to 250 g/eq.

According to one embodiment of the present disclosure, the first resin may include a hydroxyl group derived from the compound of Chemical Formula 6 at the end.

According to one embodiment of the present disclosure, the compound of Chemical Formula 6 may be a carbonate-based compound. More specifically, the compound of Chemical Formula 6 may be one selected from the group consisting of methylene carbonate, ethylene carbonate, propylene carbonate, butylene carbonate, pentylene carbonate, and combinations thereof.

According to one embodiment of the present disclosure, the first resin may include a (meth)acrylate group derived from Chemical Formula 7.

According to one embodiment of the present disclosure, the compound of Chemical Formula 7 may be an anhydride including a (meth)acrylate group.

According to one embodiment of the present disclosure, the first resin may include a carboxyl group derived from the compound of Chemical Formula 8.

According to one embodiment of the present disclosure, the compound of Chemical Formula 8 may include one or more types of phthalic anhydride, tetrahydrophthalic anhydride, maleic anhydride, succinic anhydride, and glutaric anhydride.

According to one embodiment of the present disclosure, the first resin may be prepared by reacting the compound of Chemical Formula 7 or the compound of Chemical Formula 8 with a hydroxyl group of the first base resin or a hydroxyl group produced by reacting the first base resin and the compound of Chemical Formula 6. Specifically, in the compound of Chemical Formula 6, the cyclic carbonate group included in the compound may be ring-opened to form a hydroxyl group, and a compound of the following Chemical Formula 11 may be prepared by reacting the first base resin and the compound of Chemical Formula 6. The hydroxyl group of the compound of the following Chemical Formula 11 and each of the compound of Chemical Formula 7 and the compound of Chemical Formula 8 may react to form a (meth)acrylate and a carboxyl group.

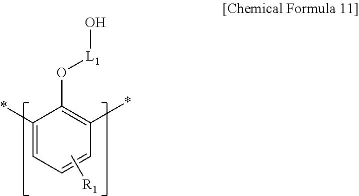

According to one embodiment of the present disclosure, the first resin may be prepared by reacting the compound of Chemical Formula 6 in an amount of greater than or equal to 0.5 moles and less than or equal to 3.0 moles with respect to 1 mole of the first base resin.

According to one embodiment of the present disclosure, the first resin may be prepared by reacting the compound of Chemical Formula 7 in an amount of greater than or equal to 0.1 moles and less than or equal to 1.5 moles with respect to 1 mole of the first base resin. Specifically, the first resin may be prepared by reacting the compound of Chemical Formula 7 with a hydroxyl group of the first base resin or a hydroxyl group at the end produced by reacting the first base resin and the compound of Chemical Formula 6, and may be prepared by reacting the compound of Chemical Formula 7 in an amount of greater than or equal to 0.1 moles and less than or equal to 1.5 moles with respect to 1 mole of the hydroxyl group at the end produced by reacting the first base resin and the compound of Chemical Formula 6.

According to one embodiment of the present disclosure, the first resin may be prepared by reacting the compound of Chemical Formula 8 in an amount of greater than or equal to 0.1 moles and less than or equal to 1.0 mole with respect to 1 mole of the first base resin. Specifically, the first resin may be prepared by reacting the compound of Chemical Formula 8 with a hydroxyl group of the first base resin or a hydroxyl group at the end produced by reacting the first base resin and the compound of Chemical Formula 6, and may be prepared by reacting the compound of Chemical Formula 8 in an amount of greater than or equal to 0.1 moles and less than or equal to 1.0 mole with respect to 1 mole of the hydroxyl group at the end produced by reacting the first base resin and the compound of Chemical Formula 6. By controlling the molar ratio of the reaction between the first base resin and the compound of Chemical Formula 8 within the above-described range, only a small amount of chlorine ions is included, thereby enhancing insulation reliability and lifetime, suppressing an occurrence of migration, and delaying the time of occurrence.

According to one embodiment of the present disclosure, the (meth)acrylate-based resin includes a second resin including repeat units of the following Chemical Formula 3 and the following Chemical Formula 4. By including the repeat units each of Chemical Formula 3 including a hydroxyl group and a (meth)acrylate group at the end and Chemical Formula 4 including a carboxyl group and a (meth)acrylate group at the end, the (meth)acrylate-based resin includes the second resin including the repeat units of Chemical Formula 3 and Chemical Formula 4, such that insulation reliability of a dry film solder resist including the (meth)acrylate-based resin may be enhanced.

According to one embodiment of the present disclosure, in the (meth)acrylate-based resin, the repeat unit of Chemical Formula 3 and the repeat unit of Chemical Formula 4 may have a molar ratio of 9:1 to 1:9. Specifically, the repeat unit of Chemical Formula 3 and the repeat unit of Chemical Formula 4 may have a molar ratio of 8:2 to 2:8, 7:3 to 3:7 or 6:4 to 4:6. By controlling the molar ratio of the repeat unit of Chemical Formula 3 and the repeat unit of Chemical Formula 4 included in the resin within the above-described range, chlorine ions generated during the (meth)acrylate-based resin preparation process may be minimized.

According to one embodiment of the present disclosure, the (meth)acrylate-based resin may include the repeat unit of Chemical Formula 3 in an amount of greater than or equal to 10 parts by mole and less than or equal to 90 parts by mole with respect to 100 parts by mole of the repeat units of the second resin. By controlling the molar ratio of the repeat unit of Chemical Formula 3 within the above-described range, an occurrence of migration may be suppressed and the time of occurrence may be delayed.

According to one embodiment of the present disclosure, the (meth)acrylate-based resin may include the repeat unit of Chemical Formula 4 in an amount of greater than or equal to 10 parts by mole and less than or equal to 90 parts by mole with respect to 100 parts by mole of the repeat units of the second resin. By controlling the molar ratio of the repeat unit of Chemical Formula 4 within the above-described range, an occurrence of migration may be suppressed and the time of occurrence may be delayed.

According to one embodiment of the present disclosure, the second resin may be prepared by reacting each of a second base resin including a repeat unit of the following Chemical Formula 9, a compound of the following Chemical Formula 10, and compounds of the following Chemical Formula 8 and Chemical Formula 10.

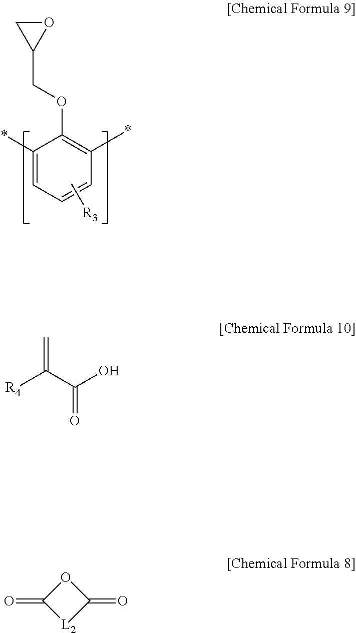

In Chemical Formula 8 to Chemical Formula 10,
R3 and R4 are each independently a substituted or unsubstituted alkyl group having 1 to 20 carbon atoms, a substituted or unsubstituted alkenyl group having 2 to 20 carbon atoms, or a substituted or unsubstituted aryl group having 6 to 15 carbon atoms,
L2 is a substituted or unsubstituted alkylene group having 1 to 10 carbon atoms, a substituted or unsubstituted alkenylene group having 2 to 10 carbon atoms, a substituted or unsubstituted cycloalkylene group having 3 to 10 carbon atoms, a substituted or unsubstituted cycloalkenylene group having 3 to 10 carbon atoms, or a substituted or unsubstituted arylene group having 6 to 15 carbon atoms, and
* represents a connection point.

According to one embodiment of the present disclosure, the second base resin may be a novolac epoxy resin. Specifically, the second base resin may be a cresol novolac epoxy resin. When the second base resin is a novolac epoxy resin, the acid group is away from the main chain, such that developability is excellent and an effect of reducing residue is obtained.

According to one embodiment of the present disclosure, the second resin may include a (meth)acrylate group derived from the compound of Chemical Formula 10.

According to one embodiment of the present disclosure, the compound of Chemical Formula 10 may be a (meth)acrylic acid, and Chemical Formula 10 may be a (meth)acrylic acid remaining after reacting the compound of Chemical Formula 11, a reaction product of the first base resin including the repeat unit of Chemical Formula 5 and the compound of Chemical Formula 6, and the compound of Chemical Formula 7 in the first resin preparation process.

According to one embodiment of the present disclosure, the second resin may include a carboxyl group derived from the compound of Chemical Formula 8.

According to one embodiment of the present disclosure, the compound of Chemical Formula 8 may include one or more types of phthalic anhydride, tetrahydrophthalic anhydride, maleic anhydride, succinic anhydride and glutaric anhydride.

According to one embodiment of the present disclosure, the second resin may be prepared by reacting the second base resin and the compound of Chemical Formula 10, and may be prepared by reacting the compound of Chemical Formula 8 with a hydroxyl group produced by reacting the second base resin and the compound of Chemical Formula 10. Specifically, in the compound of Chemical Formula 3, the ring included in the second base resin may be ring-opened by reacting the second base resin of Chemical Formula 9 and the compound of Chemical Formula 10 to form a hydroxyl group. In the compound of Chemical Formula 4, a hydroxyl group produced by reacting the second base resin and the compound of Chemical Formula 10 and one of carbonyl groups included in the compound of Chemical Formula 8 react to form an ester group, and the remaining ester group included in the compound may be the carboxyl group of the resin.

According to one embodiment of the present disclosure, the second resin may be prepared by reacting the compound of Chemical Formula 10 in an amount of greater than or equal to 0.5 moles and less than or equal to 1.5 moles with respect to 1 mole of the second base resin. Specifically, the second resin may be prepared by reacting the compound of Chemical Formula 10 in an amount of greater than or equal to 0.5 moles and less than or equal to 1.5 moles with respect to 1 mole of the epoxy group of the second base resin.

According to one embodiment of the present disclosure, the second resin may be prepared by reacting the compound of Chemical Formula 8 in an amount of greater than or equal to 0.1 moles and less than or equal to 1.0 mole with respect to 1 mole of the second base resin. Specifically, the second base resin and the compound of Chemical Formula 10 react to form a hydroxyl group, and the hydroxyl group and the compound of Chemical Formula 8 react. The number of moles of the hydroxyl group formed by reacting the second base resin and the compound of Chemical Formula 10 may be the same as the number of moles of the epoxy group of the second base resin. Accordingly, the second resin may be prepared by reacting the compound of Chemical

Formula 8 in an amount of 0.1 moles to 1.5 moles with respect to 1 mole of the hydroxyl group produced by reacting the second base resin and the compound of Chemical Formula 10. Specifically, the second resin may be prepared by reacting the compound of Chemical Formula 8 in an amount of 0.2 moles to 0.9 moles, 0.3 moles to 0.8 moles, 0.4 moles to 0.7 moles or 0.5 moles to 0.6 moles with respect to 1 mole of the epoxy group of the second base resin. By controlling the molar ratio of the reaction between the second base resin and the compound of Chemical Formula 8 within the above-described range, developability may be enhanced and low dielectric constant may be enhanced.

According to one embodiment of the present disclosure,
the first resin may be prepared by reacting ia) a first base resin including a repeat unit of the following Chemical Formula 5 or ib) a reaction product of the first base resin and a compound of the following Chemical Formula 6 and iia) a compound of the following Chemical Formula 7 or iib) a compound of the following Chemical Formula 8, and the second resin may be prepared by reacting ic) a second base resin including a repeat unit of the following Chemical Formula 9 and iic) a compound of the following Chemical Formula 10 or iid) a compound of the following Chemical Formula 10 and a compound of the following Chemical Formula 8.

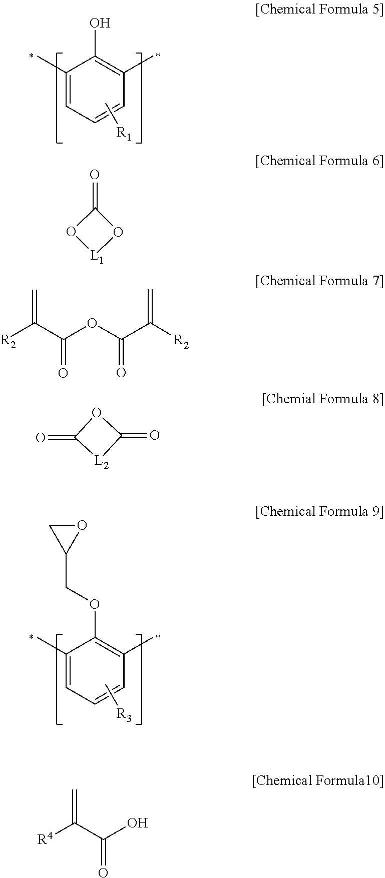

In Chemical Formula 5 to Chemical Formula 10,
R1 to R4 are each independently a substituted or unsubstituted alkyl group having 1 to 20 carbon atoms, a substituted or unsubstituted alkenyl group having 2 to 20 carbon atoms, or a substituted or unsubstituted aryl group having 6 to 15 carbon atoms,
L1 and L2 are each independently a substituted or unsubstituted alkylene group having 1 to 10 carbon atoms, a substituted or unsubstituted alkenylene group having 2 to 10 carbon atoms, a substituted or unsubstituted cycloalkylene group having 3 to 10 carbon atoms, a substituted or unsubstituted cycloalkenylene group having 3 to 10 carbon atoms, or a substituted or unsubstituted arylene group having 6 to 15 carbon atoms, and
* represents a connection point.

By preparing the first resin and the second resin as described above, the chlorine ion content may be reduced in the composition, and by having the acid group away from the main chain, developability is excellent and an effect of reducing residue is obtained.

One embodiment of the present disclosure provides a resin composition including the (meth)acrylate-based resin and an additive.

The resin composition according to one embodiment of the present disclosure contains only a small amount of chlorine ions, and therefore, is capable of enhancing insulation reliability and lifetime, suppressing an occurrence of migration, and delaying the time of occurrence.

According to one embodiment of the present disclosure, the additive may include one or more types of additives selected from among a photoinitiator, a thermally curable binder, an inorganic filler, a dispersant, a thermally curable binder catalyst, a pigment, a photocurable monomer, an ion trapping agent, an antioxidant and a filler.

According to one embodiment of the present disclosure, the additive includes one to ten types of additives selected from among a photoinitiator, a thermally curable binder, an inorganic filler, a dispersant, a thermally curable binder catalyst, a pigment, a photocurable monomer, an ion trapping agent, an antioxidant, and a filler. Specifically, two to eight types thereof may be included.

According to one embodiment of the present disclosure, the photoinitiator may enable the resin composition to initiate radical photocuring in an exposed portion.

According to one embodiment of the present disclosure, as the photoinitiator, materials such as benzoin and alkyl ethers thereof such as benzoin, benzoin methyl ether and benzoin ethyl ether; acetophenones such as acetophenone, 2,2-dimethoxy-2-phenylacetophenone, 1,1-dichloroacetophenone and 4-(1-t-butyldioxy-1-methylethyl) acetophenone; anthraquinones such as 2-methylanthraquinone, 2-amylanthraquinone, 2-t-butyl-anthraquinone and 1-chloroanthraquinone; thioxanthones such as 2,4-dimethylthioxanthone, 2,4-diisopropylthioxanthone and 2-chlorothioxanthone; ketals such as acetophenone dimethyl ketal and benzyl dimethyl ketal; and benzophenones such as benzophenone, 4-(1-t-butyldioxy-1-methylethyl)benzophenone and 3,3′,4,4′-tetrakis(t-butyldioxycarbonyl)benzophenone may be used.

In addition, as the photoinitiator, materials such as α-aminoacetophenones such as 2-methyl-1-[4-(methylthio)phenyl]-2-morpholinopropanone-1,2-benzyl-2-dimethylamino-1-(4-morpholinophenyl)-butan-1-one, 2-(dimethylamino)-2-[(4-methylphenyl)methyl]-1-[4-(4-morpholinyl)phenyl]-1-butanone and N, N-dimethylaminoacetophenone; acylphosphine oxides such as 2,4,6-trimethylbenzoyldiphenylphosphine oxide, bis(2,4,6-trimethylbenzoyl)-phenylphosphine oxide and bis(2,6-dimethoxybenzoyl)-2,4,4-trimethyl-pentylphosphine oxide; and oxime esters such as 2-(acetyloxyiminomethyl)-thioxanthen-9-one, (1,2-octanedione, 1-[4-(phenylthio)phenyl]-, 2-(O-benzoyloxime)) and (ethanone, 1-[9-ethyl-6-(2-methylbenzoyl)-9H-carbazol-3-yl]-, 1-(0-acetyloxime)) may be used. More specifically, as the photoinitiator, commercially available Irgacure (registered trademark) 907, Irgacure 369, Irgacure 379, Irgacure 819, Irgacure 2100, GGI-325, Irgacure OXE01, Irgacure OXE02 and Darocur TPO manufactured by Chiba Specialty Chemicals (currently, Chiba Japan); Lucilin (registered trademark) TPO manufactured by BASF Corporation; N-1919 manufactured by ADEKA Corporation, and the like may be used. The above-described commercially available products may be included in the photoinitiator materials described above (x-aminoacetophenones, oxime esters and the like).

According to one embodiment of the present disclosure, the amount of the photoinitiator may be from 0.5% by weight to 20% by weight, specifically from 1% by weight to 10% by weight and more specifically from 1% by weight to 5% by weight with respect to the total solid content weight of the resin composition. The resin composition solid content may mean a portion considering only components excluding a solvent and volatile components in the resin composition.

According to one embodiment of the present disclosure, the amount of the photoinitiator may be from 0.1 parts by weight to 20 parts by weight and specifically from 0.1 parts by weight to 10 parts by weight with respect to 100 parts by weight of the (meth)acrylate-based resin. By controlling the amount of the photoinitiator within the above-mentioned range, a phenomenon of improper occurrence of photocuring, which is caused by the amount of photoinitiator being less than the amount illustrated above, may be prevented, and a phenomenon of reducing resolution of the resin composition or insufficient reliability of a DFSR, which is caused by the amount of photoinitiator being greater than the amount illustrated above, may be prevented.

According to one embodiment of the present disclosure, the thermally curable binder includes a thermally curable functional group. For example, the thermally curable binder includes one or more types selected from among an epoxy group, an oxetanyl group, a cyclic ether group, and a cyclic thioether group. Such a thermally curable binder may form a crosslink with the (meth)acrylate-based resin through thermal curing to enhance heat resistance or mechanical properties of a DESR.

According to one embodiment of the present disclosure, as the thermally curable binder, a resin having two or more cyclic ether groups and/or cyclic thioether groups (hereinafter, referred to as cyclic (thio) ether groups) in the molecule; other diisocyanates or difunctional block isocyanates thereof; a polyfunctional epoxy compound having at least two or more epoxy groups in the molecule; a polyfunctional oxetane compound having at least two or more oxetanyl groups in the molecule; a compound having two or more thioether groups in the molecule, and/or the like may be used.

The thermally curable binder having two or more cyclic (thio) ether groups in the molecule may be a compound having two or more of any one or two types of groups of a 3-, 4- or 5-memered cyclic ether group, or a cyclic thioether group in the molecule.

The compound having two or more cyclic thioether groups in the molecule may be an episulfide resin. Examples of the compound having two or more cyclic thioether groups in the molecule may include bisphenol A-type episulfide resin YL7000 manufactured by Japan Epoxy Resin Co., Ltd., and the like. In addition, an episulfide resin obtained by replacing an oxygen atom of an epoxy group of a novolac-type epoxy resin with a sulfur atom, and the like may also be used.

Examples of the polyfunctional epoxy compound may include a bisphenol A-type epoxy resin, a hydrogen-added bisphenol A-type epoxy resin, a brominated bisphenol A-type epoxy resin, a bisphenol F-type epoxy resin, a bisphenol S-type epoxy resin, a novolac-type epoxy resin, a phenol novolac-type epoxy resin, a cresol novolac-type epoxy resin, an N-glycidyl-type epoxy resin, a novolac-type epoxy resin of bisphenol A, a bixylenol-type epoxy resin, a biphenol-type epoxy resin, a chelate-type epoxy resin, a glyoxal-type epoxy resin, an amino group-containing epoxy resin, a rubber-modified epoxy resin, a dicyclopentadienephenolic-type epoxy resin, a diglycidyl phthalate resin, a heterocyclic epoxy resin, a tetraglycidyl xylenoylethane resin, a silicone-modified epoxy resin, an ε-caprolactone-modified epoxy resin and the like. In addition, in order to provide flame retardancy, those having atoms such as phosphorous introduced into the structure may also be used. By thermally curing these epoxy resins, properties such as adhesiveness of cured films, solder heat resistance and electroless plating resistance are enhanced.

According to one embodiment of the present disclosure, examples of the polyfunctional oxetane compound may include, in addition to polyfunctional oxetanes such as bis [(3-methyl-3-oxetanylmethoxy)-methyl]ether, bis [(3-ethyl-3-oxetanylmethoxy)methyl]ether, 1,4-bis[(3-methyl-3-oxetanylmethoxy)methyl]benzene, 1,4-bis[(3-ethyl-3-oxetanylmethoxy)methyl]benzene, (3-methyl-3-oxetanyl)methyl acrylate, (3-ethyl-3-oxetanyl)methyl acrylate, (3-methyl-3-oxetanyl)methyl methacrylate, (3-ethyl-3-oxetanyl)methyl methacrylate, or oligomers or copolymers thereof, oxetane alcohol and a novolac resin, poly(p-hydroxystyrene), cardo-type bisphenols, calix arenes, calix resorcin arenes, or etherates with a resin having a hydroxyl group such as silsesquioxane, or the like. In addition, copolymers of an unsaturated monomer having an oxetane ring and an alkyl (meth)acrylate, and the like may also be included.

In addition, as the thermally curable binder, commercially available YDCN-500-80P and YDCN-500-90P manufactured by Kukdo Chemical Co., Ltd., and the like may be used.

According to one embodiment of the present disclosure, the amount of the thermally curable binder may be from 5 parts by weight to 50 parts by weight and specifically from 10 parts by weight to 30 parts by weight with respect to 100 parts by weight of the (meth)acrylate-based resin. When the amount of the thermally curable binder is less than the amount exemplified above, the carboxyl group remains in a DESR after curing, which reduces heat resistance, alkali resistance, electrical insulation and the like, and the amount being greater than the amount exemplified above is not preferred since film strength and the like is reduced due to the remaining thermally curable binder.

According to one embodiment of the present disclosure, the thermally curable binder catalyst may facilitate thermal curing of the thermally curable binder.

According to one embodiment of the present disclosure, as the thermally curable binder catalyst, materials such as imidazole derivatives such as imidazole, 2-methylimidazole, 2-ethylimidazole, 2-ethyl-4-methylimidazole, 2-phenylimidazole, 4-phenylimidazole, 1-cyanoethyl-2-phenylimidazole and 1-(2-cyanoethyl)-2-ethyl-4-methylimidazole; amine compounds such as dicyandiamide, benzyldimethylamine, 4-(dimethylamino)-N, N-dimethylbenzylamine, 4-methoxy-N, N-dimethylbenzylamine and 4-methyl-N, N-dimethylbenzylamine; hydrazine compounds such as adipic acid dihydrazide and sebacic acid dihydrazide; phosphorous compounds such as triphenylphosphine; and S-triazine derivatives such as guanamine, acetoguanamine, benzoguanamine, melamine, 2,4-diamino-6-methacryloyloxyethyl-S-triazine, 2-vinyl-4,6-diamino-S-triazine, 2-vinyl-4,6-diamino-S-triazine-isocyanuric acid adducts and 2,4-diamino-6-methacryloyloxyethyl-S-triazine-isocyanuric acid adducts may be used.

Specifically, as the thermally curable binder catalyst, commercially available 2MZ-A, 2MZ-OK, 2 PHZ, 2P4BHZ and 2P4MHZ (trade names of imidazole-based compounds) manufactured by Shikoku Kasei Kogyo Co., Ltd., U-CAT3503N, UCAT3502T (trade names of block isocyanate compounds of dimethylamine), DBU, DBN, U-CATS A102 and U-CAT5002 (bicyclic amidine compounds and salts thereof) manufactured by San-Apro Ltd., and the like may be used.

According to one embodiment of the present disclosure, as the thermally curable binder catalyst, a thermally curable catalyst of an epoxy resin or an oxetane compound; a catalyst facilitating a reaction of an epoxy group and/or an oxetanyl group with a carboxyl group, and the like may be used, and the above-described materials may be used either alone or as a mixture of two or more types. In addition, a compound also functioning as an adhesiveness-providing agent may be used in combination with the thermally curable binder catalyst.

According to one embodiment of the present disclosure, the amount of the thermally curable binder catalyst may be from 0.3% by weight to 2% by weight with respect to the solid content of the resin composition.

According to one embodiment of the present disclosure, the amount of the thermally curable binder catalyst may be from 0 parts by weight to 20 parts by weight and specifically from 0.1 parts by weight to 10 parts by weight with respect to 100 parts by weight of the (meth)acrylate-based resin.

According to one embodiment of the present disclosure, the inorganic filler performs a role of enhancing heat resistance stability, dimensional stability by heat and resin adhesive strength of a manufactured DFSR. In addition, it may also perform a role of an extender pigment by reinforcing colors.

According to one embodiment of the present disclosure, as the inorganic filler, a plate-type inorganic filler or a spherical silica filler may be used.

According to one embodiment of the present disclosure, the amount of the inorganic filler may be from 40% by weight to 80% by weight and specifically from 60% by weight to 70% by weight with respect to the solid content of the resin composition.

According to one embodiment of the present disclosure, the amount of the inorganic filler may be from 50 parts by weight to 1,000 parts by weight and specifically from 100 parts by weight to 500 parts by weight with respect to 100 parts by weight of the (meth)acrylate-based resin. The amount of the inorganic filler being greater than the amount exemplified above is not preferred since viscosity of the composition increases, which reduces coating property or the degree of curing. In addition, when the amount of the inorganic filler is less than the amount exemplified above, the effect of improving modulus may not be achieved, and developability and thermal expansion coefficient may be reduced.

According to one embodiment of the present disclosure, the dispersant is used for enhancing dispersion stability of the filler, the pigment and the like included in the composition, and through the use of the dispersant, micropatterns may be readily formed.

According to one embodiment of the present disclosure, as the dispersant, Tyzor AA, AA-65, AA-105 of Dorf Ketal, and the like may be used.

According to one embodiment of the present disclosure, the dispersant is preferably included in an amount of 1% by weight to 6% by weight with respect to the total solid content weight of the resin composition. When the added amount of the dispersant is too small of less than 1% by weight, dispersion is not sufficient, which may be disadvantageous for micropattern formation, and the amount of greater than 6% by weight may affect heat resistance and reliability.

According to one embodiment of the present disclosure, the pigment may exhibit visibility and hiding power to hide defects such as scratches of circuit lines.

According to one embodiment of the present disclosure, as the pigment, red, blue, green, yellow, black pigments and the like may be used. For example, phthalocyanine blue, pigment blue, pigment green, solvent green and/or pigment yellow may be used. Specifically, as the blue pigment, phthalocyanine blue, pigment blue 15:1, pigment blue 15:2, pigment blue 15:3, pigment blue 15:4, pigment blue 15:6, pigment blue 60 and the like may be used. As the green pigment, pigment green 7, pigment green 36, solvent green 3, solvent green 5, solvent green 20, solvent green 28 and the like may be used. The yellow pigment may include anthraquinone-based, isoindolinone-based, condensed azo-based, benzimidazolone-based and the like, and for example, pigment yellow 108, pigment yellow 147, pigment yellow 151, pigment yellow 166, pigment yellow 181, pigment yellow 193 and the like may be used.

According to one embodiment of the present disclosure, the amount of the pigment may be from 0.5% by weight to 3% by weight with respect to the solid content of the resin composition.

According to one embodiment of the present disclosure, the amount of the pigment may be from 0.1 parts by weight to 20 parts by weight and specifically from 0.1 parts by weight to 10 parts by weight with respect to 100 parts by weight of the (meth)acrylate-based resin. When the amount of the pigment is less than the amount exemplified above, visibility and hiding power are reduced, and when the amount of the pigment is greater than the amount exemplified above, heat resistance is reduced.

According to one embodiment of the present disclosure, the photocurable monomer may form a crosslink with an unsaturated functional group of the above-described (meth)acrylate-based resin to form a crosslinked structure by photocuring during exposure. As a result, the resin composition of the exposed portion corresponding to the portion where a DFSR is to be formed is not alkali developed and may remain on the substrate. In addition, as the photocurable monomer, those in a liquid state at room temperature may be used, and a role of adjusting viscosity of the resin composition according to the coating method or further enhancing alkali developability of the unexposed portion may also be performed.

According to one embodiment of the present disclosure, the photocurable monomer may be a compound having a photocurable unsaturated functional as a group such polyfunctional vinyl group.

According to one embodiment of the present disclosure, as the photocurable monomer, an acrylate-based compound having two or more photocurable unsaturated functional groups may be used. For example, an acrylate-based compound containing a hydroxyl group such as 2-hydroxyethyl acrylate, 2-hydroxypropyl acrylate, pentaerythritol triacrylate or dipentaerythritol pentaacrylate; a water-soluble acrylate-based compound such as polyethylene glycol diacrylate or polypropylene glycol diacrylate; a polyfunctional polyester acrylate-based compound such as trimethylolpropane triacrylate, pentaerythritol tetraacrylate or dipentaerythritol hexaacrylate; an acrylate-based compound that is an ethylene oxide adduct and/or propylene oxide adduct of polyfunctional alcohol such as trimethylolpropane or hydrogen-added bisphenol A or polyhydric phenol such as bisphenol A or biphenol; a polyfunctional or monofunctional polyurethane acrylate-based compound that is an isocyanate-modified product of hydroxyl group-containing acrylate; an epoxyacrylate-based compound that is a (meth)acrylic acid adduct of bisphenol A diglycidyl ether, hydrogen-added bisphenol A diglycidyl ether or a phenol novolac epoxy resin; and/or a caprolactone-modified acrylate-based compound such as caprolactone-modified ditrimethylolpropane tetraacrylate, acrylate of ε-caprolactone-modified dipentaerythritol, or caprolactone-modified hydroxypivalic acid neopentyl glycol ester diacrylate may be used. In addition, the above-described compounds may be used either alone or as a combination of two or more types.

According to one embodiment of the present disclosure, a polyfunctional (meth)acrylate-based compound having two or more (meth)acryloyl groups in the molecule may be used as the photocurable monomer among these, and particularly, pentaerythritol triacrylate, trimethylolpropane triacrylate (TMPTA), dipentaerythritol hexaacrylate (DPHA), caprolactone-modified ditrimethylolpropane tetraacrylate or the like may be appropriately used.

According to one embodiment of the present disclosure, the amount of the photocurable monomer may be from 1% by weight to 30% by weight or from 2% by weight to 20% by weight based on the total weight of the resin composition.

According to one embodiment of the present disclosure, the amount of the photocurable monomer may be from 1 part by weight to 40 parts by weight and specifically from 5 parts by weight to 30 parts by weight based on 100 parts by weight of the (meth)acrylate-based resin. When the amount of the photocurable monomer is less than the amount exemplified above, photocuring may not be sufficient, and when the amount is greater than the amount exemplified above, the drying property of a DFSR may become poor and physical properties may decline.

According to one embodiment of the present disclosure, as the solvent, one or more solvents may be mixed and used in order to dissolve the resin composition or to provide proper viscosity.

According to one embodiment of the present disclosure, as the solvent, ketones such as methyl ethyl ketone (MEK) and cyclohexanone; aromatic hydrocarbons such as toluene, xylene and tetramethylbenzene; glycol ethers (cellosolve) such as ethylene glycol monoethyl ether, ethylene glycol monomethyl ether, ethylene glycol monobutyl ether, diethylene glycol monoethyl ether, diethylene glycol monomethyl ether, diethylene glycol monobutyl ether, propylene glycol monomethyl ether, propylene glycol monoethyl ether, dipropylene glycol diethyl ether and triethylene glycol monoethyl ether; acetic acid esters such as ethyl acetate, butyl acetate, ethylene glycol monoethyl ether acetate, ethylene glycol monobutyl ether acetate, diethylene glycol monoethyl ether acetate, diethylene glycol monobutyl ether acetate, propylene glycol monomethyl ether acetate and dipropylene glycol monomethyl ether acetate; alcohols such as ethanol, propanol, ethylene glycol, propylene glycol and carbitol; aliphatic hydrocarbons such as octane and decane; petroleum-based solvents such as petroleum ether, petroleum naphtha, hydrogen-added petroleum naphtha and solvent naphtha; amides such as dimethylacetamide and dimethylformamide (DMF), and the like may be included. These solvents may be used either alone or as a mixture of two or more types.

According to one embodiment of the present disclosure, the amount of the solvent may be approximately from 1% by weight to 50% by weight with respect to the total weight of the resin composition.

According to one embodiment of the present disclosure, the amount of the solvent may be from 0.5 parts by weight to 40 parts by weight and specifically from 0.5 parts by weight to 20 parts by weight with respect to 100 parts by weight of the (meth)acrylate-based resin. When the amount of the solvent is less than the amount exemplified above, a coating property is reduced due to high viscosity, and when the amount is greater than the content exemplified above, stickiness increases due to poor drying.

According to one embodiment of the present disclosure, the ion trapping agent and the antioxidant may be used without limit as long as they are materials used in the art.

According to one embodiment of the present disclosure, the filler is an organic or inorganic filler, and for example, barium sulfate, barium titanate, amorphous silica, crystalline silica, fused silica, spherical silica, clay, magnesium carbonate, calcium carbonate, aluminum oxide (alumina), aluminum hydroxide, mica and the like may be used.

One embodiment of the present disclosure provides a dry film solder resist including the resin composition or a cured product of the resin composition.

The dry film solder resist according to one embodiment of the present disclosure strengthens developability, and may enhance soldering adhesiveness by reducing residue.

In one embodiment of the present disclosure, a process for manufacturing the dry film solder resist is the same as a method used in the art except for using the resin composition described above. For example, the dry film solder resist may be manufactured in the following manner.

First, a carrier film is coated with the resin composition as a photosensitive coating materials using a comma coater, a blade coater, a lip coater, a rod coater, a squeeze coater, a reverse coater, a transfer roll coater, a gravure coater, a spray coater or the like, and after drying the result by passing through an oven at a temperature of 50° C. to 130° C. for 1 minute to 30 minutes, a release film is laminated thereon to prepare a dry film formed with, from below, a carrier film, a photosensitive film and a release film.

In one embodiment of the present disclosure, the photosensitive film may have a thickness of approximately 5 μm to 100 μm.

In one embodiment of the present disclosure, as the carrier film, films plastic such as polyethylene terephthalate (PET), a polyester film, a polyimide film, a polyamideimide film, a polypropylene and a polystyrene film may be used, and as the release film, polyethylene (PE), a polytetrafluoroethylene film, a polypropylene film, a surface-treated paper or the like may be used. When peeling off the release film, adhesive strength between the photosensitive film and the release film is preferably lower than adhesive strength between the photosensitive film and the carrier film.

Next, after peeling off the release film, the photosensitive film layer is bonded on a substrate on which a circuit is formed using a vacuum laminator, a hot roll laminator, a vacuum press or the like.

Next, the substrate is exposed with light having a certain wavelength range (UV and the like). As for the exposure, the substrate may be selectively exposed using a photomask or may also be directly pattern exposed using a laser direct exposure machine. The carrier film is peeled off after the exposure. The exposure amount varies depending on the film thickness, but is preferably from 0 mJ/cm² to 1,000 mJ/cm². When performing the exposure, for example, photocuring occurs in the exposed portion, resulting in a crosslink between unsaturated functional groups, and as a result, they are not removed by subsequent development. In contrast, in the unexposed portion, the crosslink and the crosslinked structure obtained therefrom are not formed and the carboxyl group is maintained, and an alkali-developable state is obtained.

Next, development is performed using an alkali solution and the like. As the alkali solution, aqueous alkali solutions such as potassium hydroxide, sodium hydroxide, sodium carbonate, potassium carbonate, sodium phosphate, sodium silicate, ammonia and amines may be used. By such a development, only the film in the exposed portion may remain.

Lastly, a printed circuit board including the solder resist formed from the photosensitive film is completed by heat curing (post cure). The heat curing temperature is suitably 100° C. or higher.

One embodiment of the present disclosure provides a circuit board including the dry film solder resist.

In one embodiment of the present disclosure, in the circuit board, various technical constitutions known in the art may be applied without limit except for using the dry film solder resist described above.

In one embodiment of the present disclosure, the circuit board is a semiconductor circuit board.

According to one embodiment of the present disclosure, by including the first resin including the repeat units of Chemical Formula 1 and Chemical Formula 2; and the second resin including the repeat units of Chemical Formula 3 and Chemical Formula 4, the (meth)acrylate-based resin may react with an epoxy molding compound (EMC). In the (meth)acrylate-based resin of the present disclosure, Chemical Formula 1 to Chemical Formula 4 include an active ester structure and the epoxy molding compound includes an epoxy structure, and accordingly, the active ester group may react with the epoxy group as in the following Reaction Formula 1. The reaction may occur under a basic condition such as DMAP, may occur under a general organic reaction temperature (25° C.) and pressure (1 atmosphere) condition, and may also occur under a high temperature, a high pressure, or a high temperature and high pressure condition.

According to one embodiment of the present disclosure, the active ester group of the dry film solder resist and the epoxy group of the epoxy molding compound may react to increase adhesive strength between the dry film solder resist and the epoxy molding compound. In addition, most of reliability defects occurring in a semiconductor package using a board occur at an interface between a solder resist and an epoxy molding compound or an adhesive and a solder resist. Accordingly, in order to increase adhesive strength between a solder resist and an epoxy molding compound, plasma treatment is generally performed on the solder resist, however, the solder resist including the resin having an active ester group of the present disclosure may increase adhesive strength with an epoxy molding compound without plasma treatment.

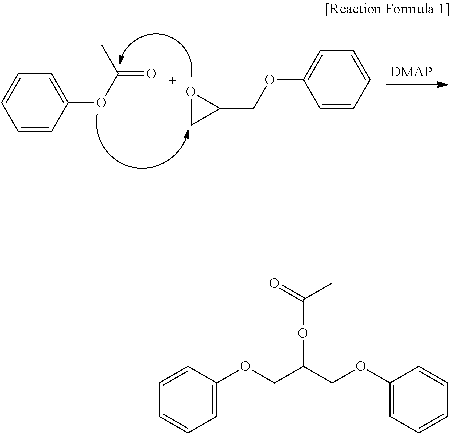

According to one embodiment of the present disclosure, adhesive strength between the dry film solder resist and the epoxy molding compound may be from 10 Kgf/cm² to 100 Kgf/cm². Specifically, the adhesive strength may be from 15 Kgf/cm² to 80 Kgf/cm², 15 Kgf/cm² to 60 Kgf/cm², 15 Kgf/cm² to 40 Kgf/cm² or 15 Kgf/cm² to 35 Kgf/cm².

### EXAMPLES

Hereinafter, the present disclosure will be described in detail with reference to examples in order to specifically describe the present disclosure. However, the examples according to the present disclosure may be modified to various different forms, and the scope of the present disclosure is not construed as being limited to the examples described below. The examples of the present specification are provided in order to more fully describe the present disclosure to those having average knowledge in the art.

### Preparation of (Meth)Acrylate-Based Resin

### Preparation Example 1

122 g of a cresol novolac resin (Nanokor NPS-9113), 88 g of ethylene carbonate (1 equivalent with respect to the cresol novolac resin), 7.89 g of triphenylphosphine and 420 g of a propylene glycol monomethyl ether acetate (PGMEA) solvent were added and reacted for 4 hours at 200° C. while blowing air thereto and stirring. After that, to the obtained reaction product, 154 g of methacrylate anhydride (1 equivalent with respect to the cresol novolac resin) and 218 g of a cresol novolac epoxy resin (Kukdo Chemical Co., Ltd. YDCN-500-90P, 1 equivalent with respect to the cresol novolac resin) were added, and the result was reacted for 16 hours at 98° C. Subsequently, 60 g of tetrahydrophthalic anhydride (0.4 equivalents with respect to the cresol novolac resin) was added thereto, and the result was reacted for 8 hours at 85° C. to prepare a (meth)acrylate-based resin having a solid content of 60%.

### Preparation Example 2

122 g of a cresol novolac resin (Nanokor NPS-9113), 88 g of ethylene carbonate (1 equivalent with respect to the cresol novolac resin), 7.89 g of triphenylphosphine and 480 g of a propylene glycol monomethyl ether acetate (PGMEA) solvent were added and reacted for 4 hours at 200° C. while blowing air thereto and stirring. After that, to the obtained reaction product, 154 g of methacrylate anhydride (1 equivalent with respect to the cresol novolac resin) and 218 g of a cresol novolac epoxy resin (Kukdo Chemical Co., Ltd. YDCN-500-90P, 1 equivalent with respect to the cresol novolac resin) were added, and the result was reacted for 16 hours at 98° C. Subsequently, 91 g of tetrahydrophthalic anhydride (0.6 equivalents with respect to the cresol novolac resin) was added thereto, and the result was reacted for 8 hours at 85° C. to prepare a (meth)acrylate-based resin having a solid content of 60%.

### Preparation Example 3

122 g of a cresol novolac resin (Nanokor NPS-9113), 176 g of ethylene carbonate (2 equivalents with respect to the cresol novolac resin), 7.89 g of triphenylphosphine and 500 g of a propylene glycol monomethyl ether acetate (PGMEA) solvent were added and reacted for 4 hours at 200° C. while blowing air thereto and stirring. After that, to the obtained reaction product, 154 g of methacrylate anhydride (1 equivalent with respect to the cresol novolac resin) and 218 g of a cresol novolac epoxy resin (Kukdo Chemical Co., Ltd. YDCN-500-90P, 1 equivalent with respect to the cresol novolac resin) were added, and the result was reacted for 16 hours at 98° C. Subsequently, 91 g of tetrahydrophthalic anhydride (0.6 equivalents with respect to the cresol novolac resin) was added thereto, and the result was reacted for 8 hours at 85° C. to prepare a (meth)acrylate-based resin having a solid content of 60%.

### Preparation Example 4

122 g of a cresol novolac resin (Nanokor NPS-9113), 88 g of ethylene carbonate (1 equivalent with respect to the cresol novolac resin), 7.89 g of triphenylphosphine and 360 g of a propylene glycol monomethyl ether acetate (PGMEA) solvent were added and reacted for 4 hours at 200° C. while blowing air thereto and stirring. After that, to the obtained reaction product, 123 g of methacrylate anhydride (0.8 equivalents with respect to the cresol novolac resin) and 174 g of a cresol novolac epoxy resin (Kukdo Chemical Co., Ltd. YDCN-500-90P, 0.8 equivalents with respect to the cresol novolac resin) were added, and the result was reacted for 16 hours at 98° C. Subsequently, 36 g of tetrahydrophthalic anhydride (0.24 equivalents with respect to the cresol novolac resin) was added thereto, and the result was reacted for 8 hours at 85° C. to prepare a (meth)acrylate-based resin having a solid content of 60%.

### Preparation Example 5

122 g of a cresol novolac resin (Nanokor NPS-9113), 88 g of ethylene carbonate (1 equivalent with respect to the cresol novolac resin), 7.89 g of triphenylphosphine and 310 g of a propylene glycol monomethyl ether acetate (PGMEA) solvent were added and reacted for 4 hours at 98° C. while blowing air thereto and stirring. After that, to the obtained reaction product, 92 g of methacrylate anhydride (0.6 equivalents with respect to the cresol novolac resin) and 130 g of a cresol novolac epoxy resin (Kukdo Chemical Co., Ltd. YDCN-500-90P, 0.6 equivalents with respect to the cresol novolac resin) were added, and the result was reacted for 16 hours at 200° C. Subsequently, 36 g of tetrahydrophthalic anhydride (0.24 equivalents with respect to the cresol novolac resin) was added thereto, and the result was reacted for 8 hours at 85° C. to prepare a (meth)acrylate-based resin having a solid content of 60%.

### Preparation Example 6

122 g of a cresol novolac resin (Nanokor NPS-9113), 88 g of ethylene carbonate (1 equivalent with respect to the cresol novolac resin), 7.89 g of triphenylphosphine and 250 g of a propylene glycol monomethyl ether acetate (PGMEA) solvent were added and reacted for 4 hours at 200° C. while blowing air thereto and stirring. After that, to the obtained reaction product, 61 g of methacrylate anhydride (0.4 equivalents with respect to the cresol novolac resin) and 87 g of a cresol novolac epoxy resin (Kukdo Chemical Co., Ltd. YDCN-500-90P, 0.4 equivalents with respect to the cresol novolac resin) were added, and the result was reacted for 16 hours at 98° C. Subsequently, 24 g of tetrahydrophthalic anhydride (0.16 equivalents with respect to the cresol novolac resin) was added thereto, and the result was reacted for 8 hours at 85° C. to prepare a (meth)acrylate-based resin having a solid content of 60%.

### Preparation Example 7

400 g of a cresol novolac resin (Nanokor NPS-9113), 250 g of methacrylate anhydride (0.5 equivalents with respect to the cresol novolac resin) and 320 g of a cresol novolac epoxy resin (Kukdo Chemical Co., Ltd. YDCN-500-90P, 0.5 equivalents with respect to the cresol novolac resin) were added, and after introducing 20 g of triphenylphosphine and 1200 g of a propylene glycol monomethyl ether acetate (PGMEA) solvent thereto, the result was reacted for 16 hours at 98° C. Subsequently, 262 g of glutaric anhydride (0.7 equivalents with respect to the cresol novolac resin) was added thereto, and the result was reacted for 8 hours at 85° C. to prepare a (meth)acrylate-based resin having a solid content of 51%.

### Preparation Example 8

400 g of a cresol novolac resin (Nanokor NPS-9113), 250 g of methacrylate anhydride (0.5 equivalents with respect to the cresol novolac resin) and 320 g of a cresol novolac epoxy resin (Kukdo Chemical Co., Ltd. YDCN-500-90P, 0.5 equivalents with respect to the cresol novolac resin) were added, and after introducing 20 g of triphenylphosphine and 1200 g of a propylene glycol the monomethyl ether acetate (PGMEA) solvent thereto, result was reacted for 16 hours at 98° C. Subsequently, 187 g of glutaric anhydride (0.5 equivalents with respect to the cresol novolac resin) was added thereto, and the result was reacted for 8 hours at 85° C. Subsequently, 100 g of tetrahydrophthalic anhydride (0.2 equivalents with respect to the cresol novolac resin) was added thereto, and the result was reacted for 8 hours at 85° C. to prepare a (meth)acrylate-based resin having a solid content of 51%.

### Comparative Preparation Example 1

205 g of a cresol novolac epoxy resin (Kukdo Chemical Co., Ltd. YDCN-500-90P), 72 g of acrylic acid (1 equivalent with respect to the cresol novolac epoxy resin), 2.6 g of triphenylphosphine and 225 g of a PGMEA solvent were added and reacted for 4 hours at 98° C. while blowing nitrogen thereto and stirring. After that, to the obtained compound, 61 g tetrahydrophthalic anhydride (0.4 equivalents with respect to the cresol novolac epoxy resin) was added, and the result was reacted for 8 hours at 85° C. to prepare a (meth)acrylate-based resin having a solid content of 60%.

### Experimental Example 1 (Measurement of Chlorine Ion Content)

For each of the resin solutions prepared in Preparation Examples and Comparative Preparation Example, a quantitative analysis on the chlorine ion content was conducted using C-IC equipment. The measured chlorine ion content based on the solid content is described in the following Table 1.

TABLE 1

| | | | | | | | | | Comparative |
|---|---|---|---|---|---|---|---|---|---|
| | Preparation | Preparation | Preparation | Preparation | Preparation | Preparation | Preparation | Preparation | Preparation |
| | Example | Example | Example | Example | Example | Example | Example | Example | Example |
| | 1 | 2 | 3 | 4 | 5 | 6 | 7 | 8 | 1 |
| C1 Ion Content | 138 | 135 | 127 | 113 | 92 | 96 | 81 | 75 | 283 |
| (Unit: mg/kg) | | | | | | | | | |

According to Table 1, it can be identified that the (meth)acrylate resins prepared in Preparation Examples 1 to 8 had a smaller Cl ion content t compared to the (meth)acrylate resin prepared in Comparative Preparation Example 1.

### Manufacture of Dry Film Solder Resist

Resin compositions described in the following Table 2 were prepared.

TABLE 2

| Content (Parts | | | | | | | | | Comparative |
|---|---|---|---|---|---|---|---|---|---|
| by Weight) | Example 1 | Example 2 | Example 3 | Example 4 | Example 5 | Example 6 | Example 7 | Example 8 | Example 1 |
| Resin Type/ | Preparation | Preparation | Preparation | Preparation | Preparation | Preparation | Preparation | Preparation | Comparative |
| Content | Example | Example | Example | Example | Example | Example | Example | Example | Preparation |
| | 1/100 | 2/100 | 3/100 | 4/100 | 5/100 | 6/100 | 7/100 | 8/100 | Example |
| | | | | | | | | | 1/100 |
| Inorganic | 246 | 246 | 246 | 246 | 246 | 246 | 246 | 246 | 246 |
| Filler | | | | | | | | | |
| Pigment | 1 | 1 | 1 | 1 | 1 | 1 | 1 | 1 | 1 |
| Photocurable | 15 | 15 | 15 | 15 | 15 | 15 | 15 | 15 | 15 |
| Monomer | | | | | | | | | |
| Thermally | 20 | 20 | 20 | 20 | 20 | 20 | 20 | 20 | 20 |
| Curable | | | | | | | | | |
| Binder1 | | | | | | | | | |
| Thermally | 1 | 1 | 1 | 1 | 1 | 1 | 1 | 1 | 1 |
| Curable | | | | | | | | | |
| Binder | | | | | | | | | |
| Catalyst | | | | | | | | | |
| Photoinitiator | 1.5 | 1.5 | 1.5 | 1.5 | 1.5 | 1.5 | 1.5 | 1.5 | 1.5 |
| Solvent | 2 | 2 | 2 | 2 | 2 | 2 | 2 | 2 | 2 |

* Pigment: pigment blue and pigment yellow 5:5 weight ratio,
* Photocurable monomer: DPHA, thermally curable binder: YDCN-500-90P 75% in MEK
* Thermally curable binder catalyst: melamine
* Photoinitiator: Irgacure 2100
* Solvent: MEK

Each of the resin compositions prepared above was coated on a PET film using a comma coater, and then dried by passing through an oven at 90° C. for 3 minutes to obtain a photosensitive film having a thickness of 15 μm. On the obtained film, a release film was laminated to manufacture a dry film solder resist formed with a carrier film (PET film), a photosensitive film, and a release film, in this order.

### Experimental Example 2 (Evaluation of Developability)

A LG-T-500GA (copper clad laminate thickness: 0.1 mm, copper foil thickness: 12 μm, manufactured by LG Chem., trade name) copper clad laminate was chemically etched to form fine roughness on the copper foil surface.

After removing the release film of the dry film manufactured using the above-described method, the result was vacuum laminated on the substrate using a vacuum laminator (MV LP-500 manufactured by Meiki Seisakusho Co., Ltd.).

After that, the result was dried for 30 minutes in an oven at 80° C., then the PET film was removed, and the result was developed for a certain period of time using a 1% by weight Na₂CO₃ alkali solution at 30° C. Whether the substrate was cleanly and completely developed was visually determined based on the following criteria.
◯: the surface completed with the development showed the same color as the surface not covered with the film
X: the surface completed with the development showed a difference in the color from the surface not covered with the film

### Experimental Example 3 (Evaluation of Residue)

A LG-T-500GA copper clad laminate was chemically etched to form fine roughness on the copper foil surface.

After removing the release film of the dry film manufactured using the above-described method, the result was vacuum laminated on the substrate using a vacuum laminator (MV LP-500 manufactured by Meiki Seisakusho Co., Ltd.)

The substrate manufactured as above was exposed to UV in a wavelength range of 365 nm at an exposure amount of 350 mJ/cm² with a photomask applied thereto. After that, the PET film was removed, the result was developed for a certain period of time using a 1% by weight Na₂CO₃ alkali solution at 31° C., and a pattern was formed.

On the inside of the 80 μm SRO (solder resist open), whether silica was present on the surface was observed using an SEM and evaluation was performed based on the following criteria.
⊚: 0
◯: 1 to 5
Δ: 5 to 10
X: more than 10

### Experimental Example 4 (Evaluation of Bias HAST Resistance)

For a LG-T-500GA copper clad laminate, which is a substrate for a print circuit board, obtained by laminating copper foil on a glass epoxy base, the copper surface was etched to form an electrode having a line/space of 30 μm/30 μm.

A resist cured product was formed in the same manner as in the preparation of the specimen for measuring the evaluation of residue of Experimental Example 3, except that this substrate was employed as the substrate for evaluation, and the entire area was exposed at an exposure amount of 350 mJ/cm² with no photomask on the substrate. After that, a voltage was applied for 300 hours under a condition of 130° C., 85% RH and 5 V, and evaluation was performed based on the following criteria.
⊚: 300 hours or longer
◯: 168 hours or longer and shorter than 300 hours
Δ: 96 hours or longer and shorter than 168 hours
X: shorter than 96 hours

### Experimental Example 5 (Evaluation of Dielectric Properties)

After laminating the dry film having a size of 15 cm×15 cm obtained in each of Examples and Comparative Example on copper foil having a size of 16 cm×16 cm, the result was subjected to up to post curing in the same manner as in the preparation of the specimen for measuring moisture absorption heat resistance and the like of Experimental Example 4, except that the entire area was exposed at an exposure amount of 400 mJ/cm² with no photomask, and then only the copper foil was etched to manufacture a DFSR specimen (cured film).

For the cured film, a dielectric constant in a 10 GHZ band was measured using a vector network analyzer of Agilent Technologies Inc. as a measuring device and a split post dielectric resonator of QWED as a measuring jig.

### Experimental Example 6 (Evaluation of Adhesive Strength)

Adhesive strength between the surface of the solder resist manufactured from the solder resist composition obtained in Examples and Comparative Example and an epoxy molding compound was measured using a shear test method.

Specifically, in Example 1 to Example 8, the solder resist surface was not subjected to plasma treatment, and, as in the FIGURE, an epoxy molding compound was molded on the solder resist surface, and the result was cured to manufacture a measurement sample in a cylinder form having a size of 3 mm×3.3 mm×2.8 mm. The measurement sample was subjected to PCT, and then a shear test was performed on 10 samples to identify an average value of adhesive strength between the solder resist surface and the epoxy molding compound.

With Comparative Example 1, adhesive strength between the solder resist surface and the epoxy molding compound was measured in the same manner as with the Examples.

In the following Table 3, experimental results measured in Experimental Examples 2 to 6 are described.

TABLE 3

| | Example | Example | Example | Example | Example | Example | Example | Example | Comparative |
|---|---|---|---|---|---|---|---|---|---|
| | 1 | 2 | 3 | 4 | 5 | 6 | 7 | 8 | Example 1 |
| Developability | ◯ | ◯ | ◯ | ◯ | ◯ | ◯ | ◯ | ◯ | Δ |
| Silica Residue | ⊚ | ⊚ | ⊚ | ⊚ | ⊚ | ⊚ | ◯ | ◯ | Δ |
| Bias HAST | ◯ | ◯ | ◯ | ◯ | ◯ | ◯ | ⊚ | ⊚ | Δ |
| Resistance | | | | | | | | | |
| Dielectric | 3.3 | 3.3 | 3.3 | 3.3 | 3.3 | 3.3 | 3.2 | 3.2 | 3.5 |
| Constant (@ | | | | | | | | | |
| 10 GHz) | | | | | | | | | |
| Adhesive | 26.5 | 16.3 | 15.9 | 21.8 | 29.3 | 19.5 | 32.2 | 31.3 | 8.2 |
| Strength | | | | | | | | | |
| (Kgf/cm²) | | | | | | | | | |

Through Table 3, it can be identified that the films manufactured in Examples 1 to 8 are excellent in all of developability, silica residue, bias HAST resistance, dielectric constant and adhesive strength, whereas the film manufactured in Comparative Example 1 are low in all of developability, silica residue, bias HAST resistance and adhesive strength.

As a result, it was identified that the (meth)acrylate-based resin according to one embodiment of the present disclosure reduced the chlorine ion content during the preparation process, which reduced the occurrence of copper migration and enhanced bias HAST resistance.

Hereinbefore, the present disclosure has been described with limited examples, however, the present disclosure is not limited thereto, and it is obvious that various changes and modifications may be made by those skilled in the art within technical ideas of the present disclosure and the range of equivalents of the claims to be described.

1. A (meth)acrylate-based resin, comprising:
a first resin including repeat units of the following Chemical Formula 1 and the following Chemical Formula 2; and
a second resin including repeat units of the following Chemical Formula 3 and the following Chemical Formula 4: 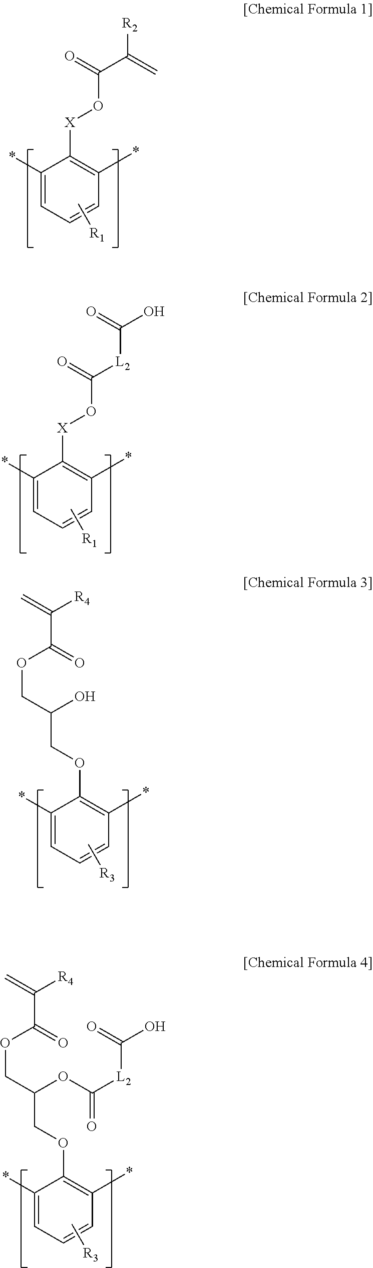
wherein, in Chemical Formula 1 to Chemical Formula 4:
R1, R2, R3 and R4 are each independently a substituted or unsubstituted alkyl group having 1 to 20 carbon atoms, a substituted or unsubstituted alkenyl group having 2 to 20 carbon atoms, or a substituted or unsubstituted aryl group having 6 to 15 carbon atoms;
X is a single bond or O-L1;
L1 and L2 are each independently a substituted or unsubstituted alkylene group having 1 to 10 carbon atoms, a substituted or unsubstituted alkenylene group having 2 to 10 carbon atoms, a substituted or unsubstituted cycloalkylene group having 3 to 10 carbon atoms, a substituted or unsubstituted cycloalkenylene group having 3 to 10 carbon atoms, or a substituted or unsubstituted arylene group having 6 to 15 carbon atoms; and
* represents a connection point.

2. The (meth)acrylate-based resin of claim 1, wherein the first resin is prepared by reacting:
ia) a first base resin including a repeat unit of the following Chemical Formula 5 or ib) a reaction product of the first base resin and a compound of the following Chemical Formula 6; and
iia) a compound of the following Chemical Formula 7, or iib) a compound of the following Chemical Formula 8: 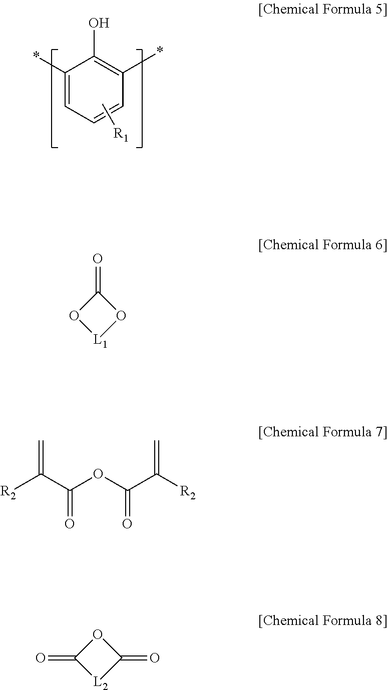
wherein in Chemical Formula 5 to Chemical Formula 8, 8:
R1 and R2 are each independently a substituted or unsubstituted alkyl group having 1 to 20 carbon atoms, a substituted or unsubstituted alkenyl group having 1-2 to 20 carbon atoms, or a substituted or unsubstituted aryl group having 6 to 15 carbon atoms;
L1 and L2 are each independently a substituted or unsubstituted alkylene group having 1 to 10 carbon atoms, a substituted or unsubstituted alkenylene group having 1-2 to 10 carbon atoms, a substituted or unsubstituted cycloalkylene group having 3 to 10 carbon atoms, a substituted or unsubstituted cycloalkenylene group having 3 to 10 carbon atoms, or a substituted or unsubstituted arylene group having 6 to 15 carbon atoms; and
* represents a connection point.

3. The (meth)acrylate-based resin of claim 2, wherein the reaction product is prepared by reacting the compound of Chemical Formula 6 in an amount of greater than or equal to 0.5 moles and less than or equal to 3.0 moles with respect to 1 mole of the first base resin.

4. The (meth)acrylate-based resin of claim 2, wherein the first base resin has a hydroxyl group equivalent of greater than or equal to 100 g/eq and less than or equal to 150 g/eq.

5. The (meth)acrylate-based resin of claim 2, wherein the reaction product of the first base resin and the compound of Chemical Formula 6 has a hydroxyl group equivalent of greater than or equal to 150 g/eq and less than or equal to 250 g/eq.

6. The (meth)acrylate-based resin of claim 2, wherein the first resin is prepared by reacting the compound of Chemical Formula 7 in an amount of greater than or equal to 0.1 moles and less than or equal to 1.5 moles with respect to 1 mole of the first base resin.

7. The (meth)acrylate-based resin of claim 2, wherein the first resin is prepared by reacting the compound of Chemical Formula 8 in an amount of greater than or equal to 0.1 moles and less than or equal to 1.0 mole with respect to 1 mole of the first base resin.

8. The (meth)acrylate-based resin of claim 1, wherein the second resin is prepared by reacting:
ic) a second base resin including a repeat unit of the following Chemical Formula 9; and
iic) a compound of the following Chemical Formula 10, or iid) a compound of the following Chemical Formula 10 and a compound of the following Chemical Formula 8: 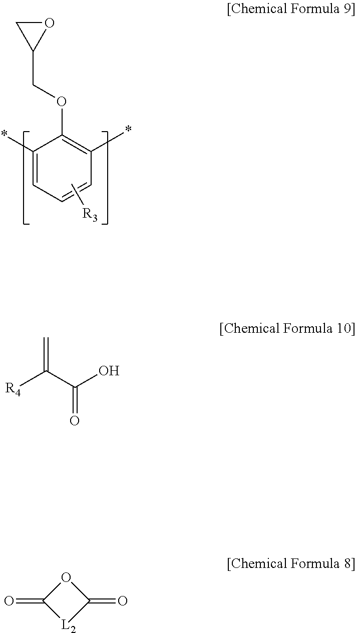
wherein in Chemical Formula 8 to Chemical Formula 10:
R3 and R4 are each independently a substituted or unsubstituted alkyl group having 1 to 20 carbon atoms, a substituted or unsubstituted alkenyl group having 2 to 20 carbon atoms, or a substituted or unsubstituted aryl group having 6 to 15 carbon atoms;
L2 is a substituted or unsubstituted alkylene group having 1 to 10 carbon atoms, a substituted or unsubstituted alkenylene group having 2 to 10 carbon atoms, a substituted or unsubstituted cycloalkylene group having 3 to 10 carbon atoms, a substituted or unsubstituted cycloalkenylene group having 3 to 10 carbon atoms, or a substituted or unsubstituted arylene group having 6 to 15 carbon atoms; and
* represents a connection point.

9. The (meth)acrylate-based resin of claim 8, wherein the second resin is prepared by reacting the compound of Chemical Formula 10 in an amount of greater than or equal to 0.5 moles and less than or equal to 1.5 moles with respect to 1 mole of the second base resin.

10. The (meth)acrylate-based resin of claim 8, wherein the second resin is prepared by reacting the compound of Chemical Formula 8 in an amount of greater than or equal to 0.1 moles and less than or equal to 1.0 mole with respect to 1 mole of the second base resin.

11. The (meth)acrylate-based resin of claim 1, wherein the first resin is prepared by reacting:
ia) a first base resin including a repeat unit of the following Chemical Formula 5 or ib) a reaction product of the first base resin and a compound of the following Chemical Formula 6; and
iia) a compound of the following Chemical Formula 7, or iib) a compound of the following Chemical Formula 8, and
the second resin is prepared by reacting:
ic) a second base resin including a repeat unit of the following Chemical Formula 9; and
iic) a compound of the following Chemical Formula 10, or iid) a compound of the following Chemical Formula 10 and a compound of the following Chemical Formula 8: 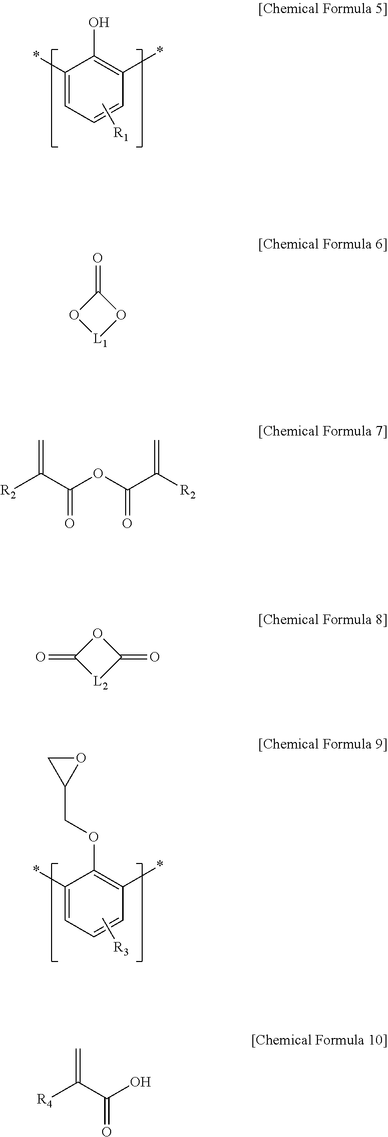
wherein in Chemical Formula 5 to Chemical Formula 10:
R1 to R4 are each independently a substituted or unsubstituted alkyl group having 1 to 20 carbon atoms, a substituted or unsubstituted alkenyl group having 1-2 to 20 carbon atoms, or a substituted or unsubstituted aryl group having 6 to 15 carbon atoms;
L1 and L2 are each independently a substituted or unsubstituted alkylene group having 1 to 10 carbon atoms, a substituted or unsubstituted alkenylene group having 1-2 to 10 carbon atoms, a substituted or unsubstituted cycloalkylene group having 3 to 10 carbon atoms, a substituted or unsubstituted cycloalkenylene group having 3 to 10 carbon atoms, or a substituted or unsubstituted arylene group having 6 to 15 carbon atoms; and
* represents a connection point.

12. A resin composition comprising:
the (meth)acrylate-based resin of claim 1; and
an additive.

13. The resin composition of claim 12, wherein the additive includes one or more additives selected from among a photoinitiator, a thermally curable binder, an inorganic filler, a dispersant, a thermally curable binder catalyst, a pigment, a photocurable monomer, an ion trapping agent, an antioxidant, and a filler.

14. A dry film solder resist, comprising the resin composition of claim 12 or a cured product of the resin composition.

15. The dry film solder resist of claim 14, wherein an active ester group of the dry film solder resist and an epoxy group of an epoxy molding compound (EMC) react to increase adhesive strength between the dry film solder resist and the epoxy molding compound.

16. The dry film solder resist of claim 14, wherein
an adhesive strength between the dry film solder resist and an epoxy molding compound is from 10 Kgf/cm² to 100 Kgf/cm².
